(19) United States
(12) Patent Application Publication
(10) Pub. No.: US 2012/0063071 A1
(43) Pub. Date: Mar. 15, 2012

(54) Machinable metal/diamond metal matrix composite compound structure and method of making same

(75) Inventors: Raouf O. Loutfy, Tucson, AZ (US); James C. Withers, Tucson, AZ (US); Juan L. Sepulveda, Tucson, AZ (US); Sharty Ibrahim, Tucson, AZ (US); Kevin Loutfy, Tucson, AZ (US)

(73) Assignee: Materials and Electrochemical Research (MER) Corporation

(21) Appl. No.: 13/135,638

(22) Filed: Jul. 12, 2011

Related U.S. Application Data
(63) Continuation-in-part of application No. PCT/US09/05032, filed on Sep. 8, 2009.
(60) Provisional application No. 61/191,315, filed on Sep. 8, 2008.

(51) Int. Cl. H05K 7/02; B32B 3/24; B32B 3/30; B32B 15/04

(52) U.S. Cl. 361/679.01; 428/686; 428/596; 428/600; 428/654

(57) ABSTRACT

A high thermal conductivity metal/diamond metal matrix composite made from diamond particles having thin layers of beta-SiC chemically bonded to the surfaces thereof, is utilized in combination with a machinable metal/carbonaceous material metal matrix composite in an integral metal matrix composite compound structure, to provide a machinable high thermal conductivity heat-dissipating substrate for electronic devices.

This application is a continuation-in-part of International Application PCT/US2009/005032, with an international filing date of Sep. 8, 2009, now abandoned, which claims the benefit of U.S. Provisional Application No. 61/191,315, filed Sep. 8, 2008, the entire contents of both of which are incorporated herein by reference.

This invention was made with Government support under Government Contract No. N00024-07-C-4120, awarded by the U.S. Navy. The Government has certain rights in the invention.

### FIELD OF THE INVENTION

This invention relates to high thermal conductivity heat-dissipating substrates for electronic devices, and more particularly, to such substrates formed of metal/diamond metal matrix composite compound structures which are easily machinable.

### BACKGROUND OF THE INVENTION

A growing demand exists for low weight packages for high power density devices like small-footprint, single chip or multi-chip, lightweight, surface mounted devices for microelectronics and optoelectronics systems requiring high thermal dissipation. Packaging of multichip modules, ball grid arrays, quad flat pack, power motor inverter drives are also useful applications of this technology.

Metal matrix composites (MMCs) are well-known materials that typically include a discontinuous particulate reinforcement phase within a continuous metal phase. An example is aluminum/diamond, Al/Diamond, which is made by infiltrating a porous, diamond preform with molten aluminum. For heat transfer applications, diamond is the best industrially available pure material, with thermal conductivity of 900-2000 W/mK. This makes diamond particles uniquely preferable to other materials for use as the discontinuous porous fraction of a metal matrix composite with the highest possible thermal conductivity.

The Al/Diamond metal matrix composite system has the desirable attributes of high thermal conductivity, very low coefficient of thermal expansion depending on the volume percentage of diamond, and light weight. These attributes make Al/Diamond metal matrix composites suitable as heat-dissipating substrates for containing or supporting electronic devices such as integrated circuit elements for which high thermal conductivity, controllable coefficient of thermal expansion (CTE), weight and other mechanical properties are all important.

An improved method for producing higher thermal conductivity Al/Diamond and other metal/diamond metal matrix composites from a metal-infiltrated porous diamond preform is described in the commonly assigned Pickard et al. U.S. Pat. No. 7,279,023, issued Oct. 9, 2007, which is incorporated herein by reference in its entirety. In accordance with the Pickard et al. method, a diamond preform component of the metal matrix composite is optimized for use in aluminum or other metal matrix, by first providing the diamond particles with thin layers of beta-SiC chemically bonded to the surfaces thereof. The SiC layer is produced in-situ on the diamond particles of the diamond preform that is then embedded in the metal matrix by a rapid high pressure metal infiltration technique known as squeeze casting. Preferably, the chemically bonded layer of SiC is produced on the diamond particles by a chemical vapor reaction process (CVR) by contacting the diamond particles with SiO gas. Such SiC-coated diamond particles when employed in metal matrix composites offer significantly improved thermal conductivity performance compared to uncoated diamond particles, with reported thermal conductivity of the resultant MMC greater than about 300 W/mK and as high as about 650 W/mK.

However, the specially-coated diamond particles necessary to achieve such high performance are expensive to produce, and once the metal/diamond composite is formed, it is very difficult to machine via conventional milling processes, because of its very high strength and extreme hardness. This lack of easy machinability poses a serious drawback to the use of these higher thermal conductivity composites as electronic device substrates requiring machined-in features, such as mounting holes or heat transfer fins.

Certain applications of metal matrix composites require different coefficients of thermal expansion or thermal conductivity for different material regions within or on a given component. Conventionally, these needs would require separate substrates, or performance tradeoffs for a single composition component structure. The concept of a single, integral metal matrix composite compound structure having regions with different compositions and properties, is disclosed in the Adams et al. U.S. Pat. Nos. 6,884,522, issued Apr. 26, 2005, and 7,141,310, issued Nov. 28, 2006. However, Adams et al. fail to teach the best means to implement this approach for the metal/diamond composite system.

### SUMMARY OF THE INVENTION

The present invention utilizes the SiC-coated diamond particles and the higher thermal conductivity metal/diamond metal matrix composites obtained therewith which are described in the above-referenced Pickard et al. U.S. Pat. No. 7,279,023, but in a more cost-effective manner, as part of an integral metal matrix composite compound structure to provide a machinable high thermal conductivity heat-dissipating substrate for electronic devices.

The substrate in accordance with the present invention comprises an integral compound body having at least one high thermal conductivity region formed of a metal/diamond metal matrix composite, and at least one machinable region formed of a metal/carbonaceous material metal matrix composite. The metal matrix in each region comprises a metal selected from among aluminum, magnesium, copper, and alloys of one or more of such metals, preferably aluminum or an aluminum alloy. The diamond in the metal/diamond metal matrix composite comprises diamond particles having thin layers of beta-SiC chemically bonded to the surfaces thereof. The carbonaceous material in the metal/carbonaceous material metal matrix composite is selected from among standard (non-pyrolytic) graphite, a carbon-carbon composite and silicon carbide. The high thermal conductivity region of the substrate will have a thermal conductivity greater than about 300 W/mK and as high as about 650 W/mK and the machinable region will typically include one or more areas that have been subjected to a machining operation in providing the substrate with its finished structure. In its finished structure, the substrate will have its high thermal conductivity region encapsulated or otherwise integrally embedded within its machinable region.

Production of the integral metal matrix composite compound body of the substrate in accordance with the present invention is carried out by first forming a porous compound preform of the diamond particles and the carbonaceous material, employing a two-piece porous rigid body of the carbonaceous material wherein the two pieces define between them one or more cavities. The diamond particles having thin layers of beta-SiC chemically bonded to the surfaces thereof are confined and compacted within at least one of the cavities, and the resulting porous compound preform is then squeeze casted with molten metal, preferably aluminum or an aluminum alloy. The metal is then solidified to thereby produce the integral metal matrix composite compound body comprising one or more high thermal conductivity regions of metal/diamond metal matrix composite integrally encapsulated within a machinable region of metal/carbonaceous material metal matrix composite. Optionally, the porous compound preform could also include one or more cavities left empty, thereby providing the resulting metal matrix composite compound body with an additional integral region of solid metal in the area of each empty cavity, which could serve, for example, as a mounting flange for the substrate. If the compound body is produced with multiple metal/diamond metal matrix composite regions, the multiple regions may be identical to each other, or they may differ in properties, for example, by varying at least one of the diamond particle relative size distribution or the volume fraction loading factor.

In this latter regard, it has been found that the thermal conductivity properties of the metal/diamond metal matrix composite regions of the compound structure produced in accordance with the present invention may be improved by proper control of the diamond particle size distribution when forming the porous compound preform. By using an appropriate mixture of coarse size (average particle diameter in the range from 80 to 200 microns) and fine size (average particle diameter in the range from 5 to 30 microns) diamond particles, with the fine size to coarse size mass ratio being in the range from 1:1 to 1:10, the fine size particles will help fill the interstitial spaces that naturally form within the distribution of the coarse size particles. Such an approach improves the thermal conductivity of the metal matrix composite by a factor of at least 10-20% as the diamond loading factor approaches its maximum value, compared to a MMC prepared with a uni-modal particle size distribution.

In the integral metal matrix composite compound body produced as described above, the machinable region typically is in the form of a block, with the high thermal conductivity region being formed as one or more block-shaped inserts or plate-shaped layers encapsulated within the machinable region block. Such compound body is then transformed into the finished structure of the substrate in accordance with the present invention, by subjecting one or more areas of the machinable region block to a machining operation. Examples of such machining operations include drilling mounting holes for the substrate through the machinable region block, milling heat transfer fins for the substrate into the machinable region block, and machining away a portion of the machinable region block to thin down certain areas thereof or to provide the substrate with an exposed surface of the high thermal conductivity region or to otherwise shape the substrate for a particular end use.

### BRIEF DESCRIPTION OF THE DRAWINGS

FIG. 1 is a schematic of a squeeze casting apparatus capable of infiltrating a compound preform with molten metal, such as aluminum.

FIG. 2 is a prior art simplified cross-section of a reactor for producing a diffusion-bonded SiC coating on diamond particles.

FIG. 3 is a schematic representation of typical electronic module package geometry, employing an insert of a metal/diamond metal matrix composite, e.g., Al/Diamond, in a block of a metal/carbonaceous material metal matrix composite, e.g., Al/Graphite.

FIG. 4 is a schematic representation of a preferred style configuration electronic module package illustrating the use of more than one Al/Diamond insert in an Al/Graphite base.

FIGS. 5(a) through 5(c) show a compound preform made from machined graphite for an Al/Diamond-Al/Graphite high power, high temperature, finned heat sink for electric motor inverters, before infiltration with aluminum, and after final machining.

FIGS. 6(a) through 6(c) show a compound preform finned heat sink similar to that of FIGS. 5(a) through 5(c), with the added feature of an aluminum mounting flange cast in place during the infiltration with aluminum.

FIGS. 7(a) and 7(b) are drawings of a graphite preform block consisting of an array of packages machined from a single block of graphite, each with a void filled with a diamond preform.

FIG. 8 is a schematic representation of how higher volumetric filling factors are attained by filling voids between larger particles with smaller particles, leading to greater thermal conductivity for the composite.

### DESCRIPTION OF PREFERRED EMBODIMENTS

In the preferred embodiments of the substrate in accordance with the present invention, the high thermal conductivity region of the integral metal matrix composite compound body is an aluminum/diamond MMC (Al/Diamond), and the machinable region is selected from among an aluminum/graphite MMC (Al/Graphite), an aluminum/carbon-carbon composite MMC (Al/C-C), and an aluminum/silicon carbide MMC (Al/SiC). Al/Graphite, Al/C-C and Al/SiC all have reasonably good thermal conductivities, as well as having coefficients of thermal expansion (CTE) which are good matches for Al/Diamond.

In the case of Al/SiC, while the thermal conductivity will increase and the CTE decrease with increasing SiC content in the MMC, too high a SiC content will adversely affect the MMC's machinability and thereby defeat its purpose in the substrate of the present invention. For this reason, the SiC content is advantageously limited to within the 25 to 45 weight percent range.

As initially produced and prior to being subjected to any machining operation, the integral metal matrix composite compound body of the substrate of the present invention will typically have its high thermal conductivity region fully encapsulated within its machinable region. Depending upon the substrate's intended end use, such encapsulation may be carried over into the substrate's finished structure, either as is or with certain areas thinned down by machining away a portion of the machinable region. In this regard, any layer of the machinable region which might interfere with heat dissipation through the substrate, is advantageously kept as thin as possible to reduce the thermal conductivity impact of the machinable region to the high thermal conductivity region. Alternatively, any such layer may be completely machined away so as to provide the substrate's finished structure with an exposed surface of the high thermal conductivity region.

The invention will be further described first with reference to the apparatus suitable for use in producing the metal matrix composite compound structure of the present invention.

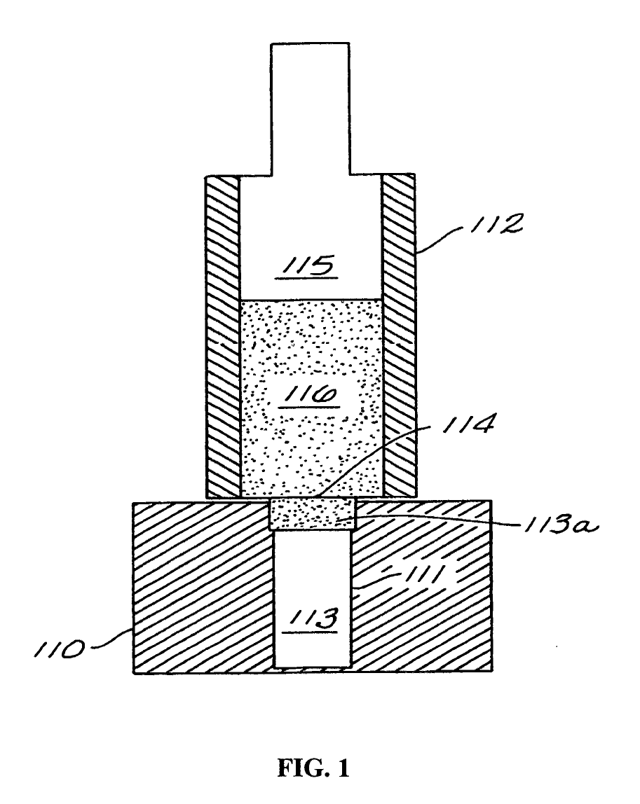

Rapid aluminum squeeze casting is a preferred technology for infiltrating the compound preform with molten metal. FIG. 1 shows a die assembly suitable for high pressure squeeze casting of metal matrix composites made in accordance with the present invention. This apparatus is fabricated from tool steel and consists of the die 110, die plug 111, and shot tube (or gate) 112. A cavity 113 is machined in the die corresponding to the required geometry for the squeeze-cast part 113a. The die plug 111 has a 0.005″ clearance to the die cavity 113 to allow air to be vented from the casting as it fills with molten aluminum. The inside diameter (ID) of the shot tube 112 is sufficiently large such that it completely covers the die cavity 113. To produce a composite casting with aluminum and a compound preform, the compound preform is placed in the die cavity 113. Ceramic paper 114 is placed in the shot tube 112 to cover the compound preform in the die 110. A quantity of molten aluminum sufficient to fill the die cavity 113 plus part of the shot tube 112 is then poured in the shot tube 112. Pressure is then applied, up to 15,000 psi via the plunger 115 to achieve a rapid filling of the die cavity 113 and achieve approximately 100% density in the metal matrix composite. After cooling, the solidified part 113a and partially filled shot tube 112 containing the biscuit 115 are removed from the die assembly. The biscuit 115 is removed by metal removal techniques such as milling or sawing to produce the desired MMC.

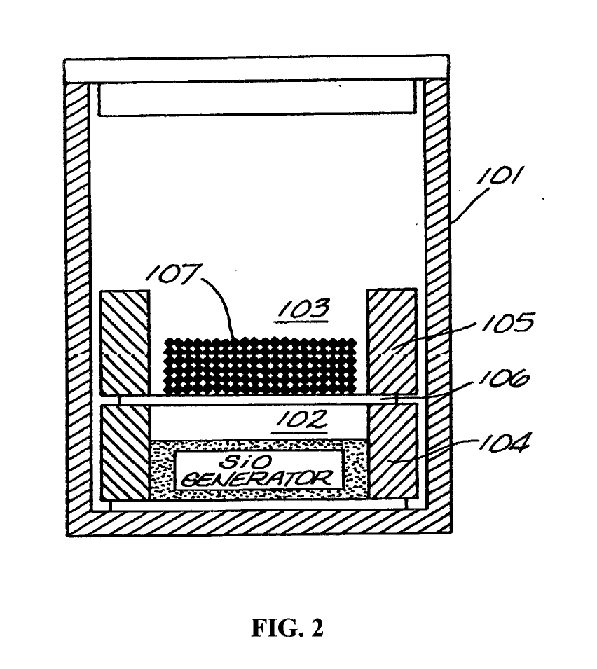

Referring now to FIG. 2, there is shown a schematic drawing of a prior art apparatus suitable for preparing diamond particles that have a conversion surface layer of beta-SiC formed thereon. In FIG. 2 there is shown in side elevation a cross sectional view of a crucible 101 formed of SiC and which is divided into a lower chamber 102 and an upper chamber 103 by means of a lower ring 104 of Si and an upper ring 105 of SiC and having a web 106 of 100% SiC fabric disposed between the two rings. The 100% SiC fabric was formed by reacting graphite fabric with gaseous SiO, to produce essentially 100% conversion of the graphite to SiC. The lower chamber 102 houses an SiO generator. The SiO generator was prepared by mixing silicon (Si) and silica (SiO₂) in equimolar ratios. As the crucible 101 is heated above 1200 degrees centigrade, SiO gas is formed from the reaction in the generator. The SiO gas produced in the lower chamber 102 passes through the SiC fabric 106 to the upper chamber 103 and reacts with an array of diamond particles 107 that are deployed on top of the SiC fabric 106 that a sufficient quantity of SiO is generated to ensure the surface of the diamond particles is converted to SiC over the entire surface of each particle.

The SiC-coated diamond particles so produced offer significantly improved thermal conductivity performance compared to uncoated diamond particles, when employed in metal matrix composites, and thus are the diamond particles which are utilized in the production of the metal matrix composite compound structures in accordance with the present invention.

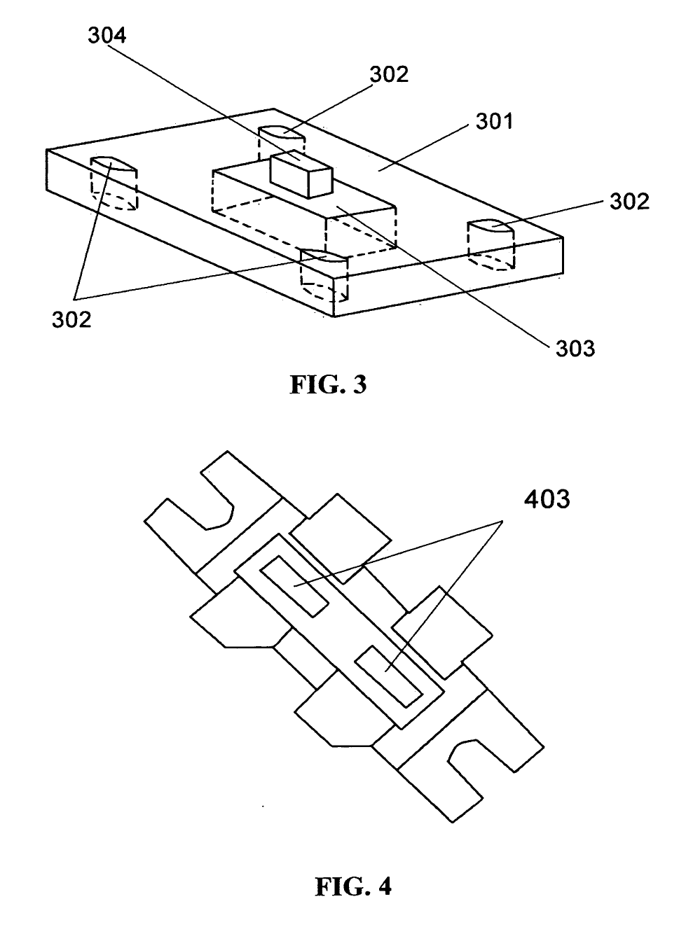

One such compound structure is shown schematically in FIG. 3. The device in this case consists of an electronic module package having an outer region 301 of Al/Graphite, with through holes 302 for mounting the package on a heat sink substrate, and an interior volume 303 of Al/Diamond. The heat-source device 304 is mounted on top of the Al/Diamond insert, which provides a channel through the base with extremely high thermal conductivity. This allows the package to provide very high thermal conductivity, at or above 500 W/mK, at the point of attachment of the powered device 304, but also allows the through holes 302 to be drilled more economically through the softer Al/Graphite MMC. Al/Graphite has reasonably good thermal conductivity, on the order of 300 W/mK, and its coefficient of thermal expansion (CTE) is a good match for Al/Diamond.

FIG. 4 extends the concept shown in FIG. 3 to incorporate more than one Al/Diamond insert 403 in the package. Such a configuration might be used in a multi-component electronic device. Thus the advanced packaging bases are made out of high thermal conductivity Al/Diamond MMC contained in package body made out of Al/Graphite. Compared to conventional copper/refractory composites like copper/tungsten (Cu/W), the novel packages are approximately 5 times lighter and 4 times more efficient in dissipating heat.

A major advantage of the instant invention derives from the use of light, low cost packaging Al/Graphite bases that use a reduced amount of high thermal conductivity Al/Diamond MMC rendering a low-cost, high thermal dissipation package not currently available in the market. Such devices can operate over a wide temperature range and provide a low production cost structure in which the use of diamond powder is minimized.

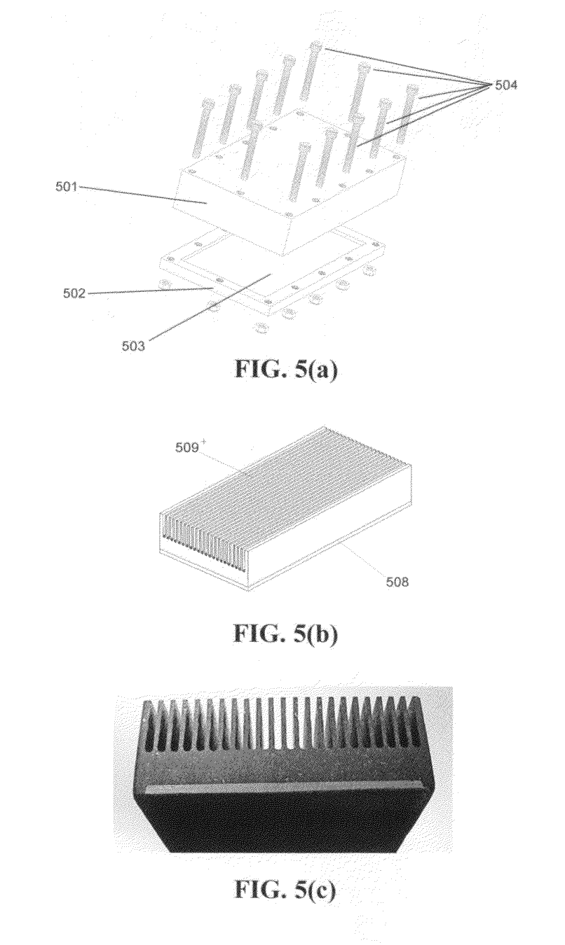

An example structure is illustrated in FIGS. 5 (a) through 5(c). These figures show a heat sink assembly, comprising a compound aluminum and Al/Diamond and Al/Graphite MMC structure. The structure is monolithic, with a large (7″×4″) foot print, power package heat sink for a motor inverter. The structure is produced by using an Al squeeze casting manufacturing process, and a bolted compound preform. First, a two-piece block of graphite, 501 and 502, is machined to provide a void comprising a shallow 0.125″ deep rectangular cavity milled into the bottom plate 502. The void 503 is filled with SiC-coated diamond powder, which is next compacted by clamping together the two pieces 501 and 502 by means of the bolts 504 to form a compacted diamond preform within the void in the porous graphite block. Advantageously, the diamond preform then requires no binders or cements, which have been found to significantly reduce the thermal conductivity of the resulting Al/Diamond MMC.

After the bolts 504 are tightened uniformly, this compound preform is heated to a temperature above the melting point of aluminum, and placed in a tool steel die in an isostatic squeeze casting machine. Molten aluminum is then poured into the die to completely immerse the compound preform in liquid metal. High pressure is next applied to the liquid aluminum, thereby squeeze-casting liquid aluminum into all voids in the porous compound preform. The molten metal next is allowed to solidify under pressure, and then the metal matrix is removed from the die. In this case, the fully infiltrated compound preform has a layer of solid aluminum surrounding the composite body.

For high volume production operations, one may alternatively pressurize the molten metal for a period of time sufficient to achieve full infiltration with liquid aluminum, and then remove the infiltrated compound preform from the die before the liquid aluminum solidifies. The amount of time required for full infiltration depends on a number of factors including the preform geometry, the preform porosity, the temperature and pressure of the squeeze casting, and the choice of alloying elements in the aluminum. The layer of aluminum metal may be partially or completely removed by further machining processes such as sawing, milling, laser cutting, water jet cutting, or EDM. The extra materials surrounding the desired structure, including the nuts and bolts and the outside layer of Al/Graphite are thus removed through the post-infiltration machining steps. In the finished product as shown in an isometric view in FIG. 5(b), and in the photograph of an actual compound MMC part shown in FIG. 5 (c), there is a solid layer 508 of high thermal conductivity Al/Diamond, and a set of lower conductivity Al/Graphite heat transfer fins 509, milled from the much softer, and therefore easier to machine, phase of the compound MMC structure. The novel approach described here solves the problem of providing complex shape requirements of the radiator fins by reducing the machining of package features to areas which are made out of Al/Graphite, and which are therefore easily machined.

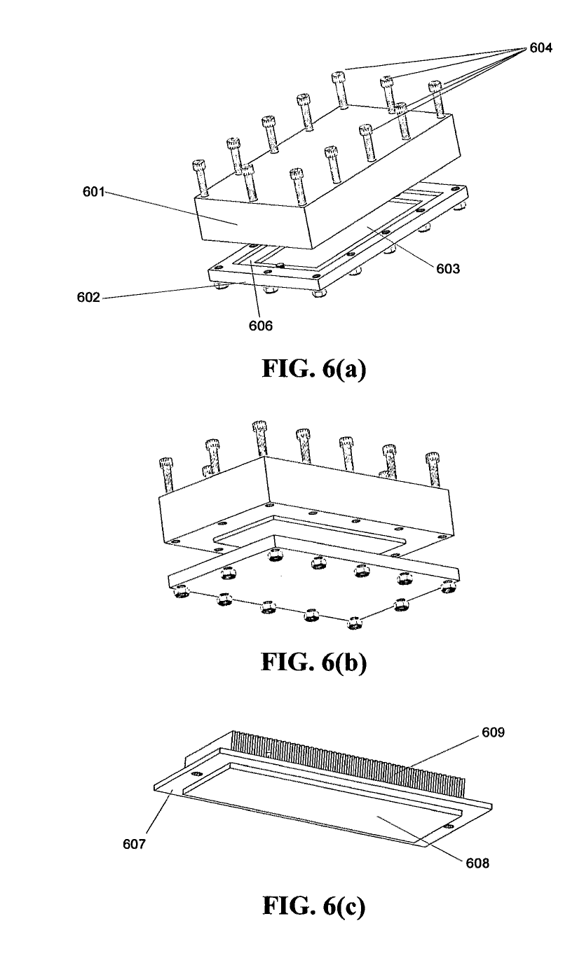

A further embodiment of the instant invention is shown in FIGS. 6(a) through 6(c). The final structure illustrated in FIG. 6(c) is similar to the device shown in FIGS. 5(b) and 5(c), except that the device of FIG. 6(c) includes an aluminum metal mounting flange that is cast at the same time that the bolted compound preform is infiltrated. The isometric view of the two-part machined graphite block 601 and 602, shown in FIG. 6 (a) shows a rectangular void comprising a shallow 0.125″ deep rectangular cavity milled into the bottom plate 602. The void 603 is filled with SiC-coated diamond powder, which is next compacted by means of the bolts 604 to form a compacted diamond preform within the void 603 in the porous graphite block. In the preform of FIG. 6(a), moreover, there is a second void 606, which remains empty when the two parts of the graphite block 601 and 602 are bolted together prior to infiltration with aluminum in the squeeze caster. This provides a simple means to manufacture a cast aluminum mounting flange 607, in the same squeeze-casting operation that infiltrates the porous graphite and diamond preform regions. Note that a sprue or vent in the form of a channel connecting the void 606 to the exterior of the compound preform may be added to allow liquid aluminum to flow more easily into the void 606 during the squeeze-casting step; however use of such a channel complicates removal of the compound preform from the die before full solidification of the matrix metal occurs. The finished part has milled Al/Graphite fins 609, a large high thermal conductivity plate of Al/Diamond 608, and cast aluminum mounting flange 607, all formed during the same infiltration step within the compound preform.

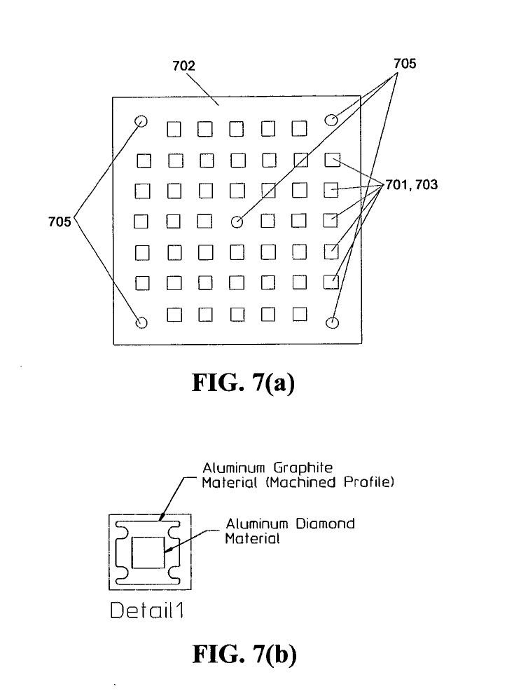

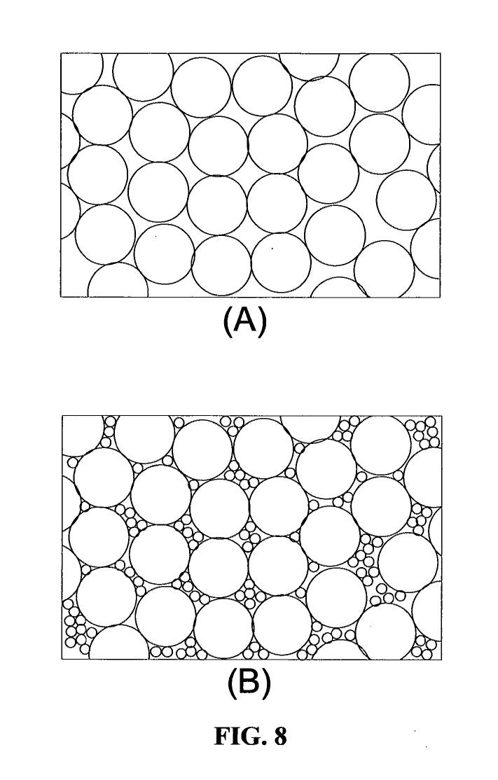

Another aspect of the instant invention is that one may produce a compound preform that comprises multiple instances of a single structure. After the compound preform is then infiltrated with metal, it may then be divided and individualized into multiple parts in a post-solidification machining process. For example, FIG. 7(a) shows an array of square voids 701 milled into a block of porous standard graphite 702. The voids 701 are filled with compacted porous diamond preforms 703. The block of graphite 702 has an overall thickness of 0.25″, and the voids have a depth of 0.125″. This planar array is designed to be bolted to a planar graphite cover not shown, by means of the five through holes 705. Once the cover 704 is secure, the entire assembly is heated, placed in a compartment in a standard squeeze-casting apparatus, immersed in liquid aluminum, and the aluminum is then pressurized to infiltrate the compound preform. After removal from the die, the excess material is removed from the complex MMC structure, and the parts are separated from each other by milling, EDM, laser cutting, or other similar procedure. A single instance of the finished high-TC compound MMC structure is shown as Detail 1 in FIG. 7(b).

The final aspect of the instant invention comprises use of multi-modal mixtures of particle sizes as a means to improve the strength, hardness, and thermal conductivity of MMCs. FIG. 8 is a schematic illustration of the principle. FIG. 8(A) shows a random arrangement of spherical particles, all the same size. Such a random distribution results in a matrix void density which is unavoidable, on the order of 35 to 50%. Steps such as vibration and pressurized compaction may reduce the void density somewhat, but especially in the case of diamond particles, which are extremely hard and virtually incompressible, other methods are needed to increase the porous preform particle density. In the specific application of heat conduction, gaps between particles are occupied by the metal matrix, which necessarily has a lower thermal conductivity than pure diamond particles. FIG. 8(B) illustrates the same arrangement of spherical particles as shown in FIG. 8 (A) but with the addition of a fraction of smaller diameter particles that have been introduced to fill the voids between the larger ones. The smaller particles therefore serve two beneficial functions to improve the thermal conductivity of the resulting MMC after infiltration: (1) they increase the relative volume of the MMC which is made of diamond, and (2) they increase the number of high conduction pathways through the resulting composite.

### Example 1

A series of experiments was performed to determine the thermal conductivity of an Al/Diamond metal matrix composite prepared using the squeeze-casting method shown in FIG. 1, with the coated particles of the diamond preform comprising two different distributions of particle sizes. The first MMC tested was a mono-modal particle size distribution of beta-SiC coated diamond particles with average size 150 micron. The second MMC tested employed a 70/30 weight percent mixture of SiC-coated diamond particles with average particle size of 150 micron and 15 micron respectively. Thermal conductivities were measured for 3 specimens of the mono-modal distribution MMC, providing an average thermal conductivity of 482 W/mK. Thermal conductivities were measured for 2 specimens of the bi-modal particle distribution MMC, providing an average thermal conductivity of 543 W/mK. This represents an increase of 61 W/mK or 12.7%.

What is claimed is:

1. A machinable high thermal conductivity heat-dissipating substrate for an electronic device, said substrate comprising an integral compound body having at least one high thermal conductivity region formed of a metal/diamond metal matrix composite, and at least one machinable region formed of a metal/carbonaceous material metal matrix composite; wherein the metal matrix in each region comprises a metal selected from the group consisting of aluminum, magnesium, copper, and alloys of one or more of said metals; the diamond in said metal/diamond metal matrix composite comprises diamond particles having thin layers of beta-SiC chemically bonded to the surfaces thereof; and the carbonaceous material in said metal/carbonaceous material metal matrix composite is selected from the group consisting of graphite, a carbon-carbon composite and silicon carbide.

2. The substrate of claim 1, wherein said machinable region includes one or more areas that have been subjected to a machining operation in providing said substrate with its finished structure.

3. The substrate of claim 2, wherein said machinable region is in the form of a block, and said high thermal conductivity region is formed as one or more inserts embedded within said block.

4. The substrate of claim 3, wherein said high thermal conductivity region is fully encapsulated within said block.

5. The substrate of claim 3, wherein said machinable region includes mounting holes for said substrate drilled through said block.

6. The substrate of claim 2, wherein said high thermal conductivity region and said machinable region are formed as separate layers of said compound body, and said machinable region layer includes heat transfer fins machined therein.

7. The substrate of claim 6, wherein said compound body also includes an additional integral layer consisting of said metal formed as a mounting flange for said substrate.

8. The substrate of claim 2, wherein said metal matrix is aluminum or an aluminum alloy.

9. The substrate of claim 8, wherein said carbonaceous material is graphite.

10. The substrate of claim 8, wherein said carbonaceous material is a carbon-carbon composite.

11. The substrate of claim 8, wherein said carbonaceous material is silicon carbide.

12. The substrate of claim 8, wherein the beta-SiC layers chemically bonded to the surfaces of the diamond particles are comprised of a conversion coating formed by a chemical vapor reaction of SiO with the diamond particles.

13. The substrate of claim 8, wherein said metal/diamond metal matrix composite has a thermal conductivity greater than about 300 W/mK and as high as about 650 W/mK.

14. The substrate of claim 13, wherein said thermal conductivity of said metal/diamond metal matrix composite is greater than about 400 W/mK.

15. The substrate of claim 13, wherein said thermal conductivity of said metal/diamond metal matrix composite is greater than about 500 W/mK.

16. The substrate of claim 13, wherein said thermal conductivity of said metal/diamond metal matrix composite is greater than about 600 W/mK.

17. The substrate of claim 8, wherein the diamond particles have a particle size distribution comprising a mixture of at least two distinct ranges of sizes, one coarse size with average particle diameter in the range from 80 to 200 microns, and one fine size with average particle diameter in the range from 5 to 30 microns, with the fine size to coarse size mass ratio being in the range from 1:1 to 1:10.

18. An electronic package comprising the substrate of claim 2, and at least one heat-generating electronic component mounted on said substrate in thermal contact with at least one of said high thermal conductivity regions of said substrate.

19. The electronic package of claim 18, wherein said metal matrix is aluminum or an aluminum alloy.

20. The electronic package of claim 19, wherein said carbonaceous material is graphite.

21. The electronic package of claim 19, wherein said carbonaceous material is a carbon-carbon composite.

22. The electronic package of claim 19, wherein said carbonaceous material is silicon carbide.

23. The electronic package of claim 18, wherein said substrate is mounted on a heat sink which is in thermal contact with said high thermal conductivity region of said substrate.
